(19) United States
(12) Patent Application Publication
(10) Pub. No.: US 2005/0275910 A1
(43) Pub. Date: Dec. 15, 2005

(54) Image scanning apparatus and image scanning program

(75) Inventor: Hayato Hokoi, Sakura-shi (JP)

Correspondence Address: OLIFF & BERRIDGE, PLC, P.O. BOX 19928, ALEXANDRIA, VA, 22320, US

(73) Assignee: NIKON CORPORATION, Chiyoda-ku (JP)

(21) Appl. No.: 10/899,134

(22) Filed: Jul. 27, 2004

(30) Foreign Application Priority Data
Aug. 8, 2003 (JP) 2003-206744

(51) Int. Cl. G03F 3/00

(52) U.S. Cl. 358/518

(57) ABSTRACT

An image scanning apparatus enables the user who lacks knowledge and experiences to easily perform image processing on the image data of a scanned original that is suitable therefor. For that purpose, the image scanning apparatus identifies at least one of a type of transmitting film originals and a picture pattern formed thereon on the basis of the image data (Ir-image data) obtained by illumination with infrared light from among the image data obtained by preparatory scanning (pre-scan), and sets up the conditions for the image processing based on the identified result.

### BACKGROUND OF THE INVENTION

1. Field of the Invention

The present invention relates to an image scanning apparatus for optically scanning images on transmitting originals and an image scanning program enabling a computer to control the image scanning apparatus.

2. Description of the Related Art

There is a conventional image scanning apparatus for optically scanning images on transmitting originals (film originals). In Japanese Unexamined Patent Application Publication No. Hei 8-339438, for example, the image scanning apparatus automatically identifies the types of transmitting originals to set various conditions according to the identified results. In the image scanning apparatus, it is identified whether the transmitting original is a positive or negative film, and scanning is performed by changing light sources according to the identified film type.

The above image scanning apparatus, however, has not been able to identify any further details other than the type of the film, positive or negative. Because of this, the user has to set the conditions for scanning and image processing in accordance with the types of the transmitting originals. To set these conditions, however, knowledge and experiences are required, so that the user who lacks them sometimes cannot make appropriate settings to effectively use the image scanning apparatus.

### SUMMARY OF THE INVENTION

An object of the present invention is to provide an image scanning apparatus and an image scanning program that enables the user who lacks knowledge and experiences to easily perform image processing on the image data of scanned originals, the processing being suitable for the scanned originals.

To achieve the above-mentioned object, according to one of the aspects of the present invention, an image scanning apparatus includes: an illumination unit illuminating a transmitting original with a plurality of illuminations of color separation elements including at least infrared light; a scanning unit scanning the image data of the transmitting original by each of the illuminations of the color separation elements; an image processing unit performing image processing on the image data obtained by the scanning unit; an identifying unit identifying at least one of a type of the transmitting original and a picture pattern formed on the transmitting original on the basis of the image data obtained by illumination with infrared light from among the image data obtained by preparatory scanning by the scanning unit; and a setting up unit setting up conditions for the image processing in the image processing unit on the basis of the identification by the identifying unit.

Further, to achieve the above-mentioned object, according to another aspect of the present invention, an image processing program, which is an image scanning program, controls an image scanning apparatus by a computer. The image scanning apparatus includes: an illumination unit illuminating a transmitting original with a plurality of illuminations of color separation elements including at least infrared light; a scanning unit scanning image data of the transmitting original by each of the illuminations of the color separation elements; and an image processing unit performing image processing on the image data obtained by the scanning unit. The program executes on the computer an identifying procedure identifying at least one of a type of the transmitting original and a picture pattern formed on the transmitting original on the basis of the image data obtained by illumination with infrared light from among the image data obtained by preparatory scanning by the scanning unit, and a setting up procedure setting up conditions for the image processing in the image processing unit on the basis of the identification by the identifying procedure.

### BRIEF DESCRIPTION OF THE DRAWINGS

FIG. 1 is a functional block diagram of an image scanning apparatus according to an embodiment of the present invention;

FIG. 2 is a flowchart showing the operation of the image scanning apparatus according to the embodiment of the present invention;

FIG. 3 is a flowchart showing the operation of the image scanning apparatus according to the embodiment of the present invention;

FIG. 4 is a flowchart showing the operation of the image scanning apparatus according to the embodiment of the present invention; and

FIG. 5 is a explanatory view showing differences between the histogram of the R-image data and that of the Ir-image data.

### DESCRIPTION OF THE PREFERRED EMBODIMENT

An embodiment of the present invention will be described with reference to the accompanying drawings.

As an exemplary image scanning apparatus of the invention, an image scanning apparatus including a film scanner for scanning images on film originals and a host computer will be described. An executable program of the invention is pre-stored in a central processing unit (CPU) in the film scanner.

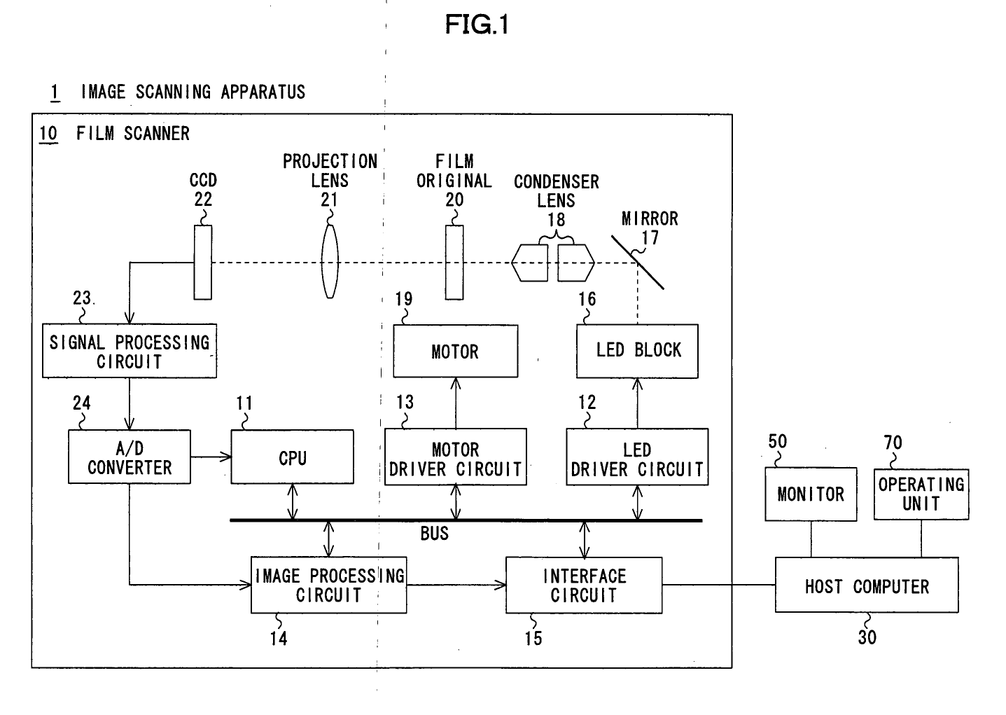

FIG. 1 is a block diagram showing an image scanning apparatus according to an embodiment of the invention.

As shown in FIG. 1, the image scanning apparatus 1 includes a film scanner 10, a host computer 30, a monitor 50, and an operating unit 70 such as a keyboard and a mouse. The monitor 50 and the operating unit 70 are connected to the host computer 30.

The film scanner 10 includes a CPU 11, a light emitting diode (LED) driver circuit 12, a motor driver circuit 13, an image processing circuit 14, and an interface circuit 15, all of which are mutually connected via a bus. The output of the image processing circuit 14 is connected to the interface circuit 15, which interconnects with the host computer 30.

The film scanner 10 further includes an LED block 16, a mirror 17, condenser lenses 18, a motor 19, a stage (not shown) for transferring a film original 20, a projection lens 21, a charge coupled device (CCD) 22, a signal processing circuit 23, an analog/digital (A/D) converter 24, and so forth. The LED driver circuit 12 is connected to the LED block 16. The output of the CCD 22 is connected to the signal processing circuit 23, which is connected to the A/D converter 24. Further, the image processing circuit 14 is connected to the A/D converter 24.

The LED block 16 includes a plurality of the quaternary LEDs for red light emission (which have a secondary peak wavelength in the infrared light region other than the red color separation wavelength), and pluralities of the quaternary LEDs for green, blue, and infrared light emissions. The LED driver circuit 12 outputs a drive signal according to commands from the CPU 11 to control timings of lighting on and off of these LEDs in the LED block 16.

The LED block 16 is thus controlled by the CPU 11 and the LED driver circuit 12 to emit the three color illuminations of red, green, and blue, which are predetermined color separation elements, and the illumination in the infrared light region. Herein, the red illumination includes the secondary peak wavelength in the infrared light region, and the illumination in the infrared light region has approximately the same wavelength as the secondary peak wavelength included in the red illumination.

The illumination emitted by the LED block 16 is reflected by the mirror 17, led to the condenser lenses 18, focused thereby, and then guided to an area for a single line width on the film original 20.

The motor 19 is driven by a drive signal output from the motor driver circuit 13 according to commands from the CPU 11, thereby enabling the stage (not shown) for transferring the film original 20 to move. The stage can move, for example, to a no film position described later, or in a sub-scanning direction when the film original 20 is scanned.

The projection lens 21 guides the transmitted light passed through the film original 20 to the CCD 22 to form an image thereon.

The CCD 22 performs photoelectric conversion in a receiver unit including a plurality of pixels internally disposed in a single line, and generates signal charges depending on the transmitted light from the film original 20. Subsequently, the signal charges are scanned to generate the image signals which are output to the signal processing circuit 23.

The signal processing circuit 23 performs, for example, a correlated double sampling process and a gain adjustment process on the image signals output from the CCD 22, and outputs the processed image signals to the A/D converter 24.

The A/D converter 24 performs A/D conversion on the image signals output from the signal processing circuit 23, and outputs the converted signals to the CPU 11 and the image processing circuit 14 as image data.

In the embodiment, to simplify the descriptions, it is assumed that the image data obtained by illumination with the light in the infrared light region is output only to the CPU 11. The image data obtained by illumination with the light in the infrared light region, red light, green light, and blue light are referred to below as Ir-image data, R-image data, G-image data, and B-image data, respectively.

The image processing circuit 14 performs image processing on the R-image data, G-image data, and B-image data, and outputs the processed image data to the interface circuit 15. The image processing performed in the image processing circuit 14 on the R-image data, G-image data, and B-image data includes a gradation conversion process, a color correction process, and a scratch correction process. The condition settings of each image processing will be described later.

The interface circuit 15 outputs the image data received from the image processing circuit 14 to the host computer 30 according to commands from the CPU 11.

The host computer 30 performs image processing for display on the image data received via the interface circuit 15 to display the processed image data on the monitor 50.

The CPU 11, the LED driver circuit 12, the LED block 16, the mirror 17, and the condenser lenses 18 correspond to an illumination unit in the claims; the CPU 11, the projection lens 21, the CCD 22, the signal processing circuit 23, and the A/D converter 24 correspond to a scanning unit in the claims; the CPU 11, and the image processing circuit 14 correspond to an image processing unit in the claims; and the CPU 11 corresponds to an identifying unit and a setting up unit in the claims. The Ir-image data and R-image data correspond to “image data obtained by illumination with infrared light” and “image data obtained by illumination with red light” in the claims, respectively. Further, the scratch correction process corresponds to “surface defect correction process” in the claims.

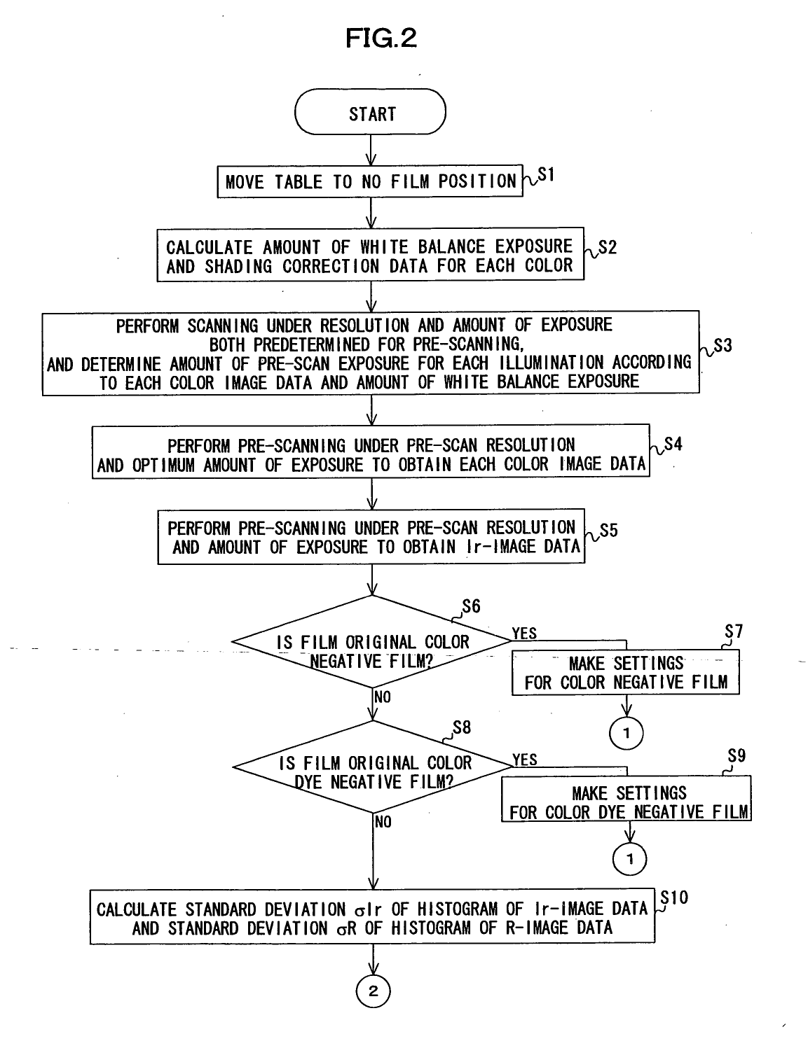

The operation of the image scanning apparatus 1 of the present embodiment will be described below with reference to FIGS. 2 to 5.

Firstly, the main power supply (not shown) is switched on, then the CPU 11 performs a predetermined initialization process and moves the stage (not shown) by controlling the motor driver circuit 13 and the motor 19 so that the illumination emitted by the LED block 16 is guided to the no film position where the film original 20 is not present (step S1 in FIG. 2).

Next, on the basis of the image data obtained by the transmitted light from the no film position, the CPU 11 calculates the amount of white balance exposure and shading correction data for each of the colors, red, green, and blue (step S2 in FIG. 2).

The amount of white balance exposure, which is used for determining the amount of exposure for each of the three color illuminations, red, green, and blue, and the shading correction data are both calculated in the same way as in the conventional image scanning apparatus.

Next, the CPU 111 controls each part of the film scanner 10 to perform scanning by illumination with each of the three color lights under a resolution (e.g. 300 dpi) and an amount of exposure both predetermined for pre-scanning. The amount of pre-scan exposure is then determined for each of the color illuminations according to the image data obtained by each scan and the above-mentioned amount of white balance exposure (step S3 in FIG. 2).

Next, the CPU 111 controls each part of the film scanner 10 to perform preparatory scanning (pre-scanning) by illumination with each of the three color lights under a pre-scan resolution and the amount of exposure determined in step S3 in FIG. 2 and obtain each color image data (step S4 in FIG. 2). In this step S4, the pre-scanning by the film scanner 10 is performed not only on part of the image but also on part of the base.

Next, the CPU 111 controls each part of the film scanner 10 to perform preparatory scanning (pre-scanning) by illumination with the light in the infrared light region under a pre-scan resolution and the amounts of exposure determined in step S3 in FIG. 2 and obtain the Ir-image data (step S5 in FIG. 2).

Next, the CPU 11 identifies whether the film original 20 is a color negative film or not.

The CPU 11 analyses the color balance of the base parts of the R-image data, G-image data, and B-image data from among the image data obtained in step S4, and identifies that the film original 20 is a color negative film when the red (R) density is lower than a predetermined density (step S6 in FIG. 2).

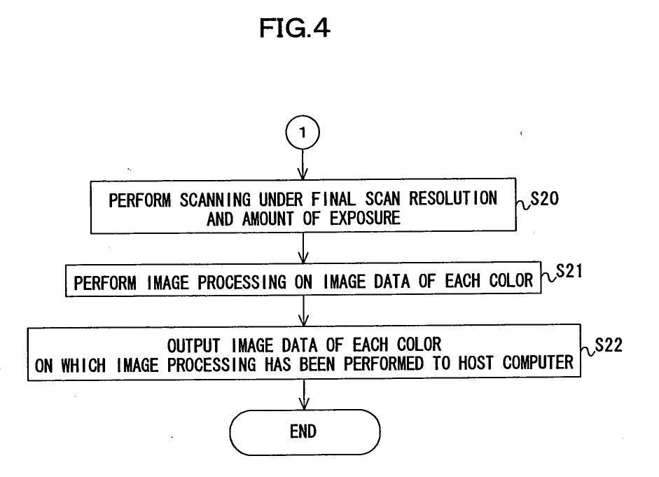

When the CPU 11 identifies that the film original 20 is a color negative film, it makes settings for the color negative film (step S7 in FIG. 2, described in detail later) and performs a final scan (steps S20 to S22 in FIG. 4).

When the CPU 11 identifies that the film original 20 is not a color negative film, then it identifies whether the film original 20 is a color dye negative film or not.

The CPU 11 analyses the base part of the G-image data from among the color image data obtained in step S4, and identifies that the film original 20 is a color dye negative film when the green (G) density is lower than a predetermined density (step S8 in FIG. 2).

When the CPU 11 identifies that the film original 20 is a color dye negative film, it makes settings for the color dye negative film (step S9 in FIG. 2, described in detail later) and performs a final scan (steps S20 to S22 in FIG. 4).

When the CPU 11 identifies that the film original 20 is not a color dye negative film, then the CPU 11 calculates the standard deviation σIr of the histogram of the Ir-image data and the standard deviation σR of the histogram of the R-image data (step S10 in FIG. 2).

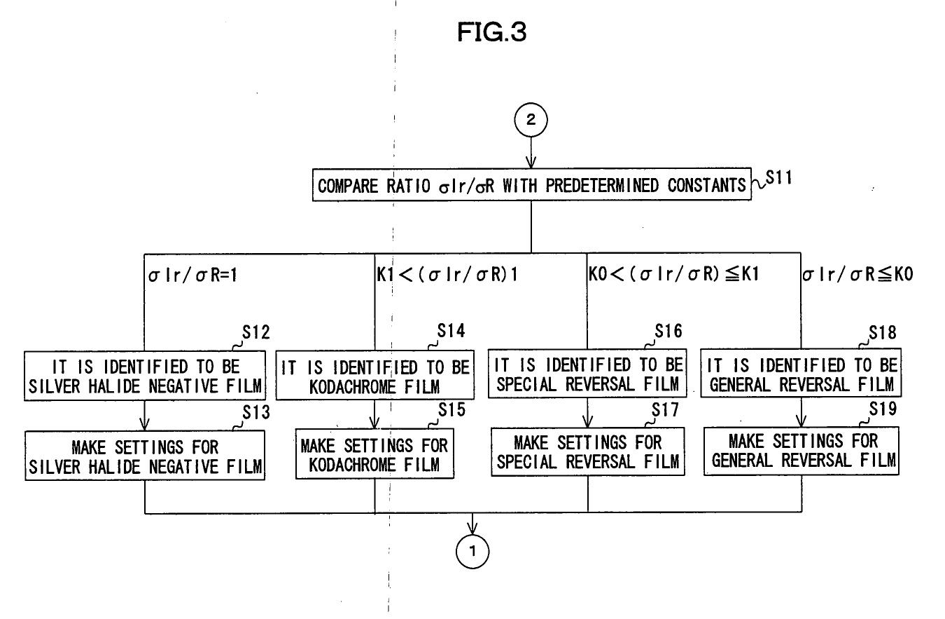

Subsequently, the CPU 11 calculates the ratio between these standard deviations (σIr/σR) to compare with predetermined constants (step S11 in FIG. 3).

The relationship between these standard deviations and types of the film originals 20 will now be described. In the descriptions, a silver halide negative film, a general reversal film, a special reversal film, and a kodachrome™ film will be taken as examples.

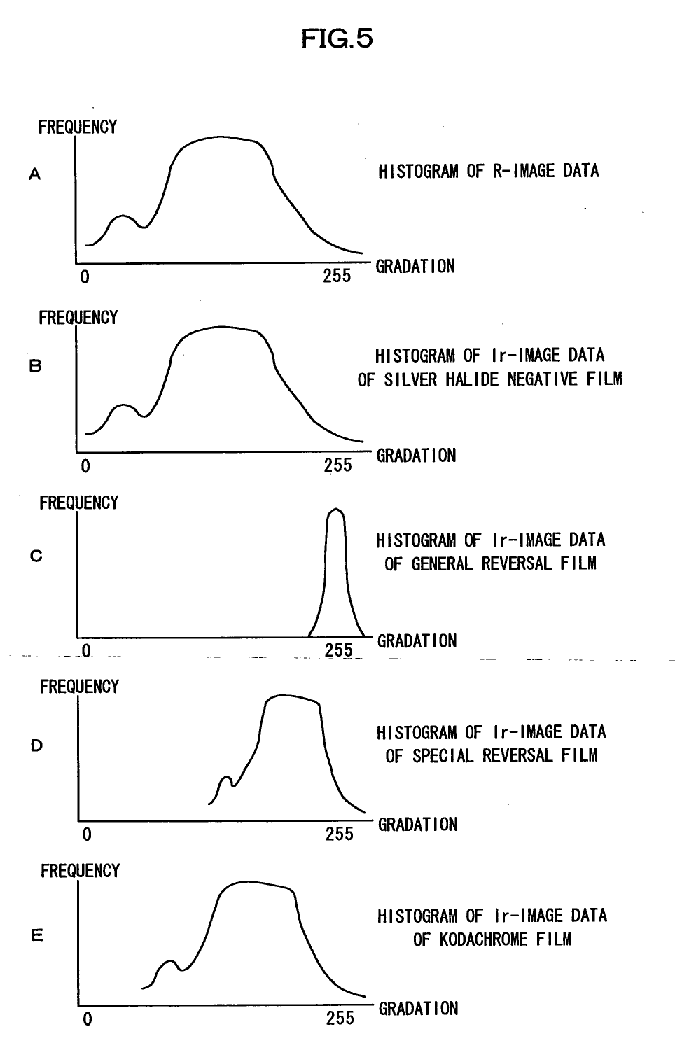

When the film original 20 is a silver halide negative film, generally the Ir-image data and the R-image data show similar shapes of the histograms. Therefore, when the R-image data shows the shape of the histogram as shown in FIG. 5A, the Ir-image data has the shape of the histogram as shown in FIG. 5B.

When the film original 20 is a general reversal film, the frequencies of gradations of the Ir-image data generally gather around the maximum gradation. Therefore, when the R-image data shows the shape of the histogram as shown in FIG. 5A, the Ir-image data has the shape of the histogram as shown in FIG. 5C.

When the film original 20 is a special reversal film, the frequencies of gradations of the Ir-image data generally distribute in the higher gradation range than the R-image data, with a certain distribution width. Therefore, when the R-image data shows the shape of the histogram as shown in FIG. 5A, the Ir-image data has the shape of the histogram as shown in FIG. 5D.

When the film original 20 is a kodachrome film, the frequencies of gradations of the Ir-image data generally distribute in the higher gradation range than the R-image data, with a slightly narrower distribution width than the special reversal film. Therefore, when the R-image data shows the shape of the histogram as shown in FIG. 5A, the Ir-image data has the shape of the histogram as shown in FIG. 5E.

Accordingly, when the ratio (σIr/σR) between the standard deviation air of the histogram of the Ir-image data and the standard deviation σR of the histogram of the R-image data satisfies the following condition 1, the CPU 11 identifies that the film original 20 is a silver halide negative film (step S12 in FIG. 3).
σIr/σR=1 condition 1

Furthermore, when the ratio (σIr/σR) between the standard deviation σIr of the histogram of the Ir-image data and the standard deviation σR of the histogram of the R-image data satisfies the following condition 2, the CPU 11 identifies that the film original 20 is a kodachrome film (step S14 in FIG. 3).
K1<(σIr/σR)<1 (where K1 is about from 0.7 to 0.8) condition 2

Furthermore, when the ratio (σIr/σR) between the standard deviation σIr of the histogram of the Ir-image data and the standard deviation σR of the histogram of the R-image data satisfies the following condition 3, the CPU 11 identifies that the film original 20 is a special reversal film (step S16 in FIG. 3).
K0<(σIr/σR)≦K1 (where K0 is about from 0.2 to 0.3 and K1 is about from 0.7 to 0.8) condition 3

Furthermore, when the ratio (σIr/σR) between the standard deviation air of the histogram of the Ir-image data and the standard deviation σR of the histogram of the R-image data satisfies the following condition 4, the CPU 11 identifies that the film original 20 is a general reversal film (step S18 in FIG. 3).
(σIr/σR)≦K0 (where K0 is about from 0.2 to 0.3) condition 4

As described above, the CPU 11 identifies the types of the film originals 20.

When the CPU 11 identifies that the film original is a silver halide negative film, it makes settings for the silver halide negative film (step S13 in FIG. 3, described in detail later) and then performs a final scan (steps S20 to S22 in FIG. 4). When the CPU 11 identifies that the film original is a kodachrome film, it makes settings for the kodachrome film (step S15 in FIG. 3, described in detail later) and then performs a final scan (steps S20 to S22 in FIG. 4).

When the CPU 11 identifies that the film original is a special reversal film, it makes settings for the special reversal film (step S17 in FIG. 3, described in detail later) and then performs a final scan (steps S20 to S22 in FIG. 4). When the CPU 11 identifies that the film original is a general reversal film, it makes settings for the general reversal film (step S19 in FIG. 3, described in detail later) and then performs a final scan (steps S20 to S22 in FIG. 4).

As described above, the CPU 11 calculates the ratio (σIr/σR) between the standard deviation σIr of the histogram of the Ir-image data and the standard deviation σR of the histogram of the R-image data, and compares it with the predetermined constants, thereby identifying the types of the film originals 20. In this case, however, the identification may be failed depending on picture patterns formed on the film original 20. In such a case, the CPU 11 identifies not only the types of the film originals 20 but also the picture patterns, whereby the conditions for the image processing are set more appropriately for the originals.

Next, the CPU 11 controls relevant parts to perform a final scan.

First, the CPU 111 controls each part of the film scanner 10 to perform scans by illuminating with the three colors, red, green, and blue, respectively, under a final scan resolution and the amount of exposure (determined according to the result of the pre-scan) (step S20 in FIG. 4).

Next, on the image data of each color obtained by the above scanning, the CPU 11 performs image processing through the image processing circuit 14 under setting conditions described later (step S21 in FIG. 4).

Finally, the CPU 11 outputs the image data of each color, on which the image processing has been performed, to the host computer 30 via the interface circuit 15 (step S22 in FIG. 4).

Next, the condition settings of the image processing for each film type, which have been described in steps S7 and S9 in FIG. 2 and steps S13, S15, S17, and S19 in FIG. 3, will be described further in detail. In these steps, the conditions are set for gradation conversion, color correction, and scratch correction processes all performed in the image processing circuit 14.

Firstly, the gradation conversion process will be described. As mentioned above, the red illumination in the embodiment includes a secondary peak wavelength in the infrared light region other than the red color separation wavelength. Accordingly, the secondary peak wavelength acts as an extra spectrum (leakage), so that the density level of the R-image data is increased more than the original density level of the film original 20. As a result, for example, red offset occurs in the dark part of the image, which leads to a loss of linearity in the reproductive characteristic of red color. Therefore, in a gradation conversion process, when the gradation conversion is performed on the R-image data from among the image data of respective colors, a correction process depending on the leakage is performed on the image data whose density level is increased more than the original one by the leakage corresponding to the extra spectrum of the red illumination (corresponding illumination). To perform such correction, a plurality of LUTs (look up tables) are pre-installed in the image processing circuit 14 and any one of the LUTs is set as a condition for the correction.

Next, the color correction process will be described. To perform the color correction process, a plurality of color correction tables are pre-installed in the image processing circuit 14 and any one of the tables is set as a condition for the correction. The color correction tables are provided to perform color corrections appropriate for respective types of the film originals.

To perform the scratch correction process, either a standard Ir light source or an Ir light source for the kodachrome film, both previously prepared, is set as a condition for the process.

1. Color Negative Film (Step S7 in FIG. 2)

Since any increase in the density level due to the aforementioned extra spectrum does not occur, the condition for the gradation correction process is set to use the LUT performing a normal gradation conversion without any corrections, selected from the plurality of LUTs pre-installed in the image processing circuit 14.

The condition of the color correction process is set to use the color correction table for the color negative film, selected from the plurality of color correction tables pre-installed in the image processing circuit 14.

The condition of the scratch correction process is set to use the standard Ir light source.

2. Color Dye Negative Film (Step S9 in FIG. 2)

Since any increase in the density level due to the aforementioned extra spectrum does not occur, the condition of the gradation correction process is set to use the LUT performing a normal gradation conversion without any corrections, selected from the plurality of LUTs pre-installed in the image processing circuit 14.

Since the film is in black-and-white, the color correction is not necessary. Accordingly, the condition of the color correction process is set so as not to perform the color correction.

The condition of the scratch correction process is set to use the standard Ir light source.

3. Silver Halide Negative Film (Step S13 in FIG. 3)

Since any increase in the density level due to the aforementioned extra spectrum does not occur, the condition of the gradation correction process is set to use the LUT performing a normal gradation conversion without any corrections, selected from the plurality of LUTs pre-installed in the image processing circuit 14.

Since the film is in black-and-white, the color correction is not necessary. Accordingly, the condition of the color correction process is set so as not to perform the color correction.

The condition of the scratch correction process is set so as not to perform the scratch correction because the scratch correction process is invalid.

4. Kodachrome Film (Step S15 in FIG. 3)

The increase in density level due to the aforementioned extra spectrum occurs depending on the gradation changes. Therefore, the condition of the gradation correction process is set to use a LUT selected from the plurality of LUTs pre-installed in the image processing circuit 14, the selected LUT performing a normal gradation conversion and also the correction in which values changing depending on gradations of the R-image data are subtracted from the R-image data.

The condition of the color correction process is set to use the color correction table for the kodachrome film, correcting red (R) and blue (B), selected from the plurality of color correction tables pre-installed in the image processing circuit 14.

The condition of the scratch correction process is set to use the Ir light source for the kodachrome.

5. Special Reversal Film (Step S17 in FIG. 3)

The increase in density level due to the aforementioned extra spectrum occurs depending on the gradation changes. Therefore, the condition of the gradation correction process is set to use a LUT selected from the plurality of LUTs pre-installed in the image processing circuit 14, the selected LUT performing a normal gradation conversion and also the correction in which values changing depending on gradations of the R-image data are subtracted from the R-image data.

The condition of the color correction process is set to use the color correction table for the special reversal film, slightly correcting R and B, selected from the plurality of color correction tables pre-installed in the image processing circuit 14.

The condition of the scratch correction process is set to use the standard Ir light source.

6. General Reversal Film (Step S19 in FIG. 3)

The increase in density level due to the aforementioned extra spectrum shows a constant value regardless of the gradation changes. Therefore, the condition of the gradation correction process is set to use a LUT selected from the plurality of LUTs pre-installed in the image processing circuit 14, the selected LUT performing a normal gradation conversion and also the correction in which the constant value is subtracted from the R-image data.

The condition of the color correction process is set to use the color correction table for the general reversal film, having input and output both equal for each color, selected from the plurality of color correction tables pre-installed in the image processing circuit 14.

The condition of the scratch correction process is set to use the standard Ir light source.

As described above, according to the embodiment, the types of the transmitting film originals and picture patterns thereon are identified on the basis of the Ir-image data from among the image data obtained by pre-scanning, and then appropriate conditions for the image processing are automatically set on the basis of the identified results. An appropriate image processing can thereby be performed according to the types of the transmitting film originals and picture patterns thereon. In the embodiment, the conditions for the image processing are thus set based on the identifications, so that even the user who lacks the knowledge and experiences can easily perform the image processing that is suitable for the original. Further, since picture patterns formed on the transmitting original are identified and then the conditions for the image processing are set based on the identifications, the conditions for the image processing that is more appropriate for the original can be set.

According to the embodiment, the identifications are made on the basis of the R-image data in addition to the Ir-image data, thereby enabling the identifications to be more highly accurate. Accordingly, even the user who lacks the knowledge and experiences can easily perform the image processing that is more suitable for the original.

Particularly, according to the embodiment, since the conditions for the color correction process are set based on the identifications, even the user who lacks the knowledge and experiences can easily perform the color correction process that is more suitable for the original.

According to the embodiment, since the conditions for the scratch correction process (surface defect correction process) are set based on the identifications, even the user who lacks the knowledge and experiences can easily perform the surface defect correction process that is more suitable for the original.

According to the embodiment, since the conditions for the correction process depending on the leakage which corresponds to the extra spectrum of the illumination are set based on the identifications, even the user who lacks the knowledge and experiences can easily perform the correction process that is more suitable for the original.

In the embodiment, a silver halide negative film, a kodachrome film, a special reversal film, and a general reversal film have been described as exemplary types of the film originals 20 to be identified by using the R-image data and the Ir-image data, but more types may be further identified by changing the values of the constants (K0, K1).

In the embodiment, the R-image data (the image data obtained by illumination with red light) and the Ir-image data (the image data obtained by illumination with infrared light) have been described as an example in which both are used for the identifications, but only the Ir-image data may be used for the identifications.

In the embodiment, the host computer 30 may be used instead of the CPU 11 in the film scanner 10, by pre-storing the image scanning program according to the invention into the host computer 30.

1. An image scanning apparatus comprising:
an illumination unit illuminating a transmitting original with a plurality of illuminations of color separation elements including at least infrared light;
a scanning unit scanning image data of said transmitting original by each of the illuminations of the color separation elements;
an image processing unit performing image processing on the image data obtained by said scanning unit;
an identifying unit identifying at least one of a type of said transmitting original and a picture pattern formed on said transmitting original on the basis of the image data obtained by illumination with infrared light from among the image data obtained by preparatory scanning by said scanning unit; and
a setting up unit setting up conditions for the image processing in said image processing unit on the basis of the identification by said identifying unit.

2. The image scanning apparatus according to claim 1, wherein:
said illumination unit emits illumination including at least said infrared light and red light; and
said identifying unit makes the identification on the basis of image data obtained by illumination with said red light in addition to the image data obtained by illumination with said infrared light.

3. The image scanning apparatus according to claim 1, wherein:
said image processing unit performs the image processing including at least a color correction process, on the image data obtained by said scanning unit; and
said setting unit sets conditions for said color correction process.

4. The image scanning apparatus according to claim 1, wherein:
said image processing unit performs the image processing including at least a surface defect correction process, on the image data obtained by said scanning unit; and
said setting unit sets conditions for said surface defect correction process.

5. The image scanning apparatus according to claim 1, wherein:
said image processing unit performs a correction process, depending on leakage, on the image data whose density level is increased more than the original one by the leakage corresponding to an extra spectrum of the corresponding illumination from among the image data obtained by said scanning unit; and
said setting unit sets conditions for said correction process depending on the leakage.

6. An image scanning program for controlling an image scanning apparatus by a computer, the image scanning apparatus comprising: an illumination unit illuminating a transmitting original with a plurality of illuminations of color separation elements including at least infrared light; a scanning unit scanning image data of said transmitting original by each of the illuminations of the color separation elements; and an image processing unit performing image processing on the image data obtained by said scanning unit, the program executing on the computer
an identifying procedure identifying at least one of a type of said transmitting original and a picture pattern formed on said transmitting original on the basis of the image data obtained by illumination with infrared light from among the image data obtained by preparatory scanning by said scanning unit, and
a setting up procedure setting up conditions for the image processing in said image processing unit on the basis of the identification by said identifying procedure.
